(19) United States
(12) Patent Application Publication
(10) Pub. No.: US 2010/0321865 A1
(43) Pub. Date: Dec. 23, 2010

(54) Electronic Apparatus with Embedded Power Supply Device

(76) Inventors: Ching-Chuan HUANG, Taipei (TW); Chih-Wei CHEN, Taipei (TW)

Correspondence Address: HDLS IPR Services, PO Box 220746, Chantilly, VA, 20153, US

(21) Appl. No.: 12/487,681

(22) Filed: Jun. 19, 2009

(51) Int. Cl. H05K 7/00

(52) U.S. Cl. 361/679.01

(57) ABSTRACT

An electronic apparatus with an embedded power supply device includes a base, a power supply device, and an accommodating structure disposed on the base for accommodating the power supply device, a first connector disposed on the accommodating structure, and a second connector disposed on the power supply device. The first connector is removably connected with the second connector. The accommodating structure has a fixing structure disposed thereon for securely fixing the power supply device thereon.

### BACKGROUND

1. Field of the Invention

The present invention relates to a base structure of an electronic apparatus, and more particularly to a base structure of an electronic apparatus that has an embedded power supply device.

2. Description of Related Art

In today's most electronic devices, a power supply device such as a power adapter is an indispensable component. In addition to voltage transformation, the power supply device usually has other functions such as rectifying current with bridge rectifiers, stabilizing voltage with capacitors, noise filtering, surge protection with a fuse and etc.

Referring to FIG. 1, for example, for an electronic apparatus 1 such as a LCD (liquid crystal display) or a notebook computer, a power supply device 3 is usually additionally included. The power supply device 3 can usually be adapted to use commercial AC (alternative current) voltages in different countries, ranging from 100V to 240V. When the power supply device 3 is connected to an AC outlet by an electric cord 5, the commercial AC power source will drive the power supply device 3 to work, upon which the power supply device 3 can feed DC (direct current) voltage and current to the electronic apparatus 1 and thereby drive the electronic apparatus 1 to work.

A conventional power supply device of an electronic apparatus, such as the power supply device 3 in FIG. 1, has an electric cord 5 at a side thereof, and the electric cord 5 has a power plug at an end thereof for being plugged into an AC outlet to receive power. A DC cord 4 is connected to another side of the power supply device 3 for connecting the power supply device 3 to the electronic apparatus 1. In this way, the power supply device 3 is driven by the power coming from the AC outlet to provide DC voltage and current to the electronic apparatus 1.

Generally speaking, the lengths of the electric cords 4 and 5 affect the dissipation of the electric power transmitted by the electric cords. The longer the electric cords are, the more is the electric power dissipated through transmission. In addition, longer electric cords are more subject to physical damages such as being bit by animals, rusty connection or cores caused by incomplete insulating layer wrapping and etc.

With current technology, a regular power supply device includes a circuit that transforms AC power into DC power and therefore it is difficult to make the power supply device too small without sacrificing the efficiency or the driving capability of the power supply device. Thus, with the size of the power supply device 3 and the DC and AC power cords 4 and 5 connected thereto, it is not convenient to collect the power supply device 3 or to carry it along with the electronic apparatus 1.

It is understood that although winding the electric cords 4 and 5 may make collecting the power supply device 3 easier and make the cords look better when winded, the winded cords may generate a lot of heat caused by electromagnetic induction, which may melt the cords, especially the insulating layer of the cords and result in short circuit and danger. Thus it is desired to have an appropriate space to place the power supply device 3 and the related electric cords to eliminate the messy look of the cords and the safety concerns thereof.

### BRIEF SUMMARY

The present invention relates to an electronic apparatus with an embedded power supply device, wherein a structure for accommodating the power supply device is disposed on a base of the electronic apparatus, and the power supply device is directly mounted to the base of the electronic apparatus through connectors, so as to decrease the possibility of the electric cords being damaged when being exposed to the outside and improve the stability of the power supply.

The present invention further relates to an electronic apparatus with an embedded power supply device, wherein a structure for accommodating the power supply device is disposed on a base of the electronic apparatus, and the power supply device is directly mounted to the base of the electronic apparatus through connectors, so that an electric cord connecting the power supply device and the electronic apparatus and transmitting DC power to the electronic apparatus is no longer required, and thereby the electromagnetic interference received by the electric cord can be eliminated and the power supply device can provide more stable voltage and current to the electronic apparatus. In addition, by reducing a DC electric cord, it is more convenient to collect the power supply device and the cost associated with the electric cord is saved.

A preferred embodiment of the present invention provides an electronic apparatus with an embedded power supply device. The electric apparatus includes a base, a power supply device, and an accommodating structure disposed on the base for accommodating the power supply device. A first connector is disposed on the base, and a second connector is disposed on the power supply device. The first connector is removably connected with the second connector. In addition, the power supply device includes an electric cord for receiving power from an external power source. When the first connector is electrically connected to the second connector, the power is provided to the electronic apparatus.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a schematic view of a conventional electronic apparatus in connection with a power supply device thereof;

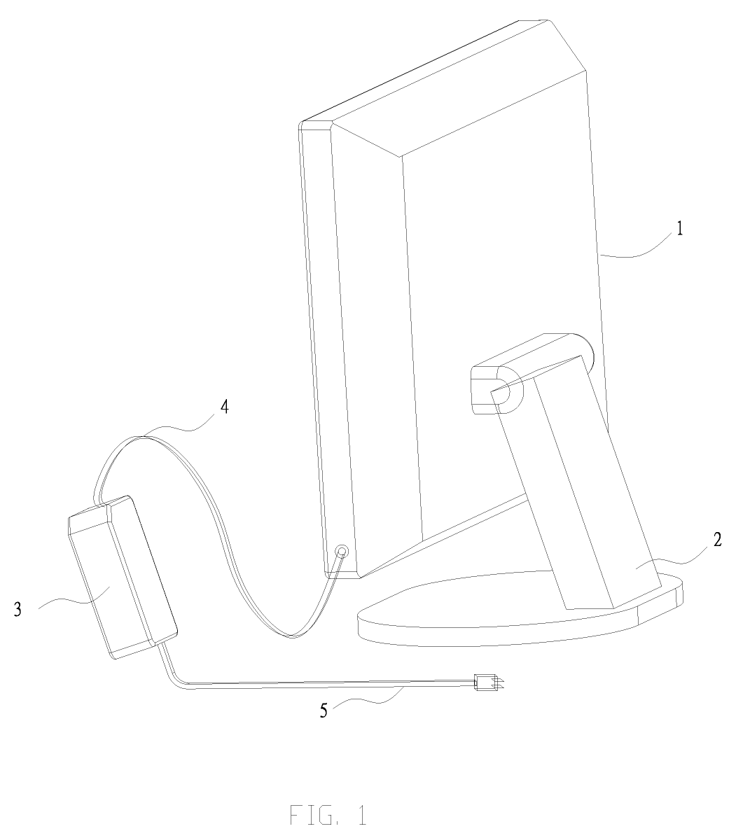

FIG. 2 is a schematic view of an electronic apparatus according to an embodiment of the present invention, when being separated from a power supply device thereof.

### DETAILED DESCRIPTION

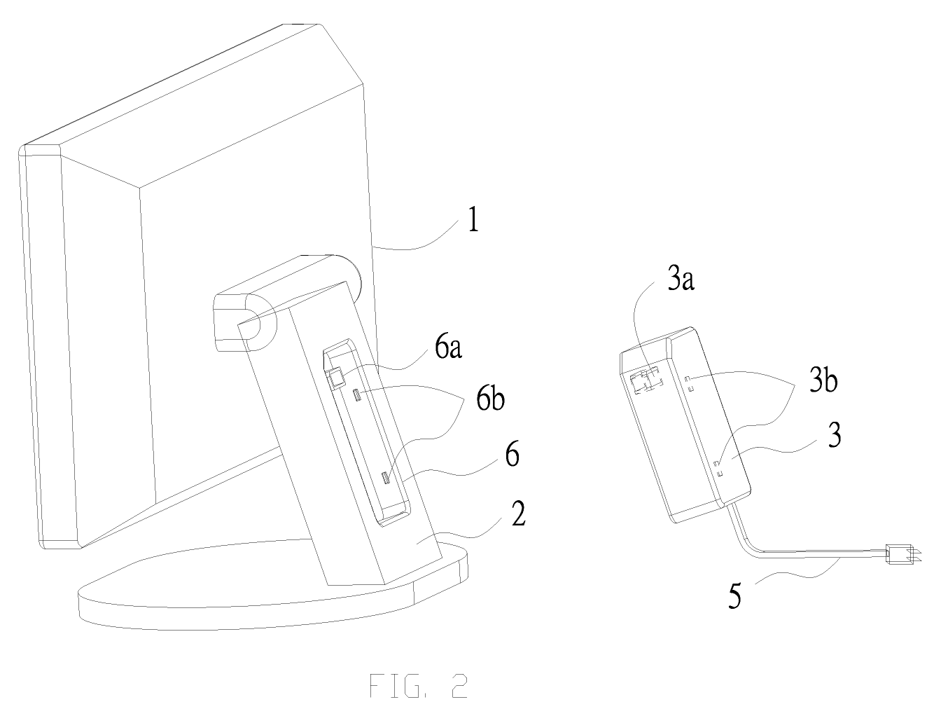

Referring to FIG. 2, an electronic apparatus 1 according to an embodiment of the present invention is provided. The electronic apparatus 1 has a base 2. The base 2 is normally positioned below the main body of the electronic apparatus 1 and configured for mechanically support the main body. In this embodiment, a power supply device 3 is combined with the base 2 to make it more convenient for a user to use the electronic apparatus 1.

An accommodating structure 6 is disposed on the base 2 and configured for accommodating the power supply device 3. The accommodating structure 6 can have many forms as long as the power supply device 3 can be contained, collected or placed in the accommodating structure 6. For example, the accommodating structure 6 can be a containing space, a groove-shaped space, a concave hole, or a trench hole, as long as the power supply device 3 can be placed, ejected or inserted into the accommodating structure 6.

Referring to FIG. 2, in this embodiment, a first fixing structure 6b can be disposed on the accommodating structure 6. Corresponding to the first fixing structure 6b, a second fixing structure 3b can be disposed on the power supply device 3. Through the second fixing structure 3b, the first fixing structure 6b can support, be clipped with, or be buckled up with the power supply device 3 so that the power supply device 3 can be tightly engaged with the accommodating structure 6 of the base 2.

Referring to FIG. 2, in this embodiment, the power supply device 3 can be an adaptor, or alternatively, can be an electricity storage device or a battery. For example, the power supply device 3 can be a battery box with one or multiple batteries inside, or a Lithium-ion battery that can be charged and discharged for many times. When the power supply device 3 is engaged with the accommodating structure 6 on the base 2, a first connector 6a, which is disposed on the accommodating structure 6, is electrically connected to a second connector 3a, which is disposed on the power supply device 3, so as to transmit the voltage and current for the electronic apparatus 1 to work. In addition, the first connector 6a and the second connector 3a have a fool-proof mechanism to prevent the user from making an erroneous connection therebetween.

In the above embodiment, the accommodating structure 6 is disposed on the base 2 of the electronic apparatus 1 for accommodating the power supply device 3. The first connector 6a is disposed on the accommodating structure 6. The second connector 3a is disposed on the power supply device 3. The first connector 6a and the second connector 3a can be removably connected with each other. Comparing to the conventional technology, a DC electric cord is reduced in this embodiment so that the cost associated therewith is saved.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. An electronic apparatus with an embedded power supply device, comprising:
a base;
a first connector disposed on the base; and
a power supply device having a second connector; wherein the first connector is removably connected with the second connector.

2. The electronic apparatus of claim 1, wherein the base is configured for mechanically supporting the electronic apparatus.

3. The electronic apparatus of claim 1, wherein the base comprises an accommodating structure for accommodating the power supply device.

4. The electronic apparatus of claim 3, wherein the accommodating structure is a containing space, a groove-shaped space, a concave hole, or a trench hole, for the power supply device to be placed in or inserted into.

5. The electronic apparatus of claim 3, wherein the accommodating structure comprises a first fixing structure, and the power supply device comprises a second fixing structure, the second fixing structure being configured to be removably engaged with the first fixing structure.
